(19) United States
(12) Patent Application Publication
(10) Pub. No.: US 2012/0034769 A1
(43) Pub. Date: Feb. 9, 2012

(54) LOW TEMPERATURE MICROWAVE ACTIVATION OF HEAVY BODY IMPLANTS

(76) Inventors: Robert J. Purtell, West Jordan, UT (US); Dixie Dunn, Salt Lake City, UT (US)

(21) Appl. No.: 13/204,017

(22) Filed: Aug. 5, 2011

Related U.S. Application Data
(60) Provisional application No. 61/371,013, filed on Aug. 5, 2010.

(51) Int. Cl. H01L 21/265

(52) U.S. Cl. 438/530; 257/E21.334

(57) ABSTRACT

Semiconductor devices and methods for making such devices are described. The semiconductor devices contain dopant regions that have been formed by low temperature, microwave activation of implanted dopants. In some configurations, the low temperature microwave activation can be used to control the final location of the implant, with or without additional drive-in or implant processes. In some configurations, this control can be used to create heavy body implants. Microwave activation of source regions and well regions in the semiconductor devices can also be used to optimize the implants where supplemental drive-in processes may be necessary to get the required final implant depth. By activating the implanted dopants using lower temperatures, many of the unwanted features introduced into the semiconductor devices by high temperature Rapid Thermal Process (RTP) can be avoided. Other embodiments are described.

### CROSS-REFERENCE TO RELATED APPLICATION

This patent application claims priority of U.S. Provisional Application Serial No. 61/371,013, filed on Aug. 5, 2010, the entire disclosure of which is hereby incorporated by reference.

### FIELD

This application relates generally to semiconductor devices and methods for making such devices. More specifically, this application describes semiconductor devices containing dopant regions that have been activated by the application of microwaves at low wafer processing temperatures.

### BACKGROUND

Semiconductor devices containing integrated circuits (ICs) or discrete devices are used in a wide variety of electronic apparatus. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning Silicon wafers are typically used as the substrate and photolithography is used to mark different areas of the substrate to be doped or to deposit and define polysilicon, insulators, or metal layers.

Often, these layers contain a dopant region that changes the insulating or conducting properties of the semiconductor material in which it is located, typically a silicon substrate. The dopant region is formed by implanting the dopant atoms into the semiconductor material and then activating the dopant by thermally heating it, causing the release of a free electron (or hole) from the dopant material into the surrounding substrate.

### SUMMARY

This application describes semiconductor devices and methods for making such devices. The semiconductor devices contain dopant regions that have been formed by low temperature, microwave activation of implanted dopants. In some configurations, the low temperature microwave activation can be used to control the final location of the implant, with or without additional drive-in or implant processes. In some configurations, this control can be used to create electrically active dopant regions from the heavy body implant. Microwave activation of source regions and well regions in the semiconductor devices can also be used to optimize the implants where supplemental drive-in processes, pre-microwave processing may be necessary to get the required final implant depth. By activating the implanted dopants using lower temperatures, many of the unwanted features introduced into the semiconductor devices by high temperature Rapid Thermal Process (RTP) can be avoided.

### BRIEF DESCRIPTION OF THE DRAWINGS

The following description can be better understood in light of the Figures, in which:

FIG. 1 shows some embodiments of a UMOS (U-shaped MOSFET) semiconductor structure.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. The same reference numerals in different drawings represent the same element, and thus their descriptions will not be repeated. As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while the description refers to UMOS (U-shaped MOSFET) semiconductor devices, it could be modified for any other types of semiconductor devices such as CMOS and LDMOS devices.

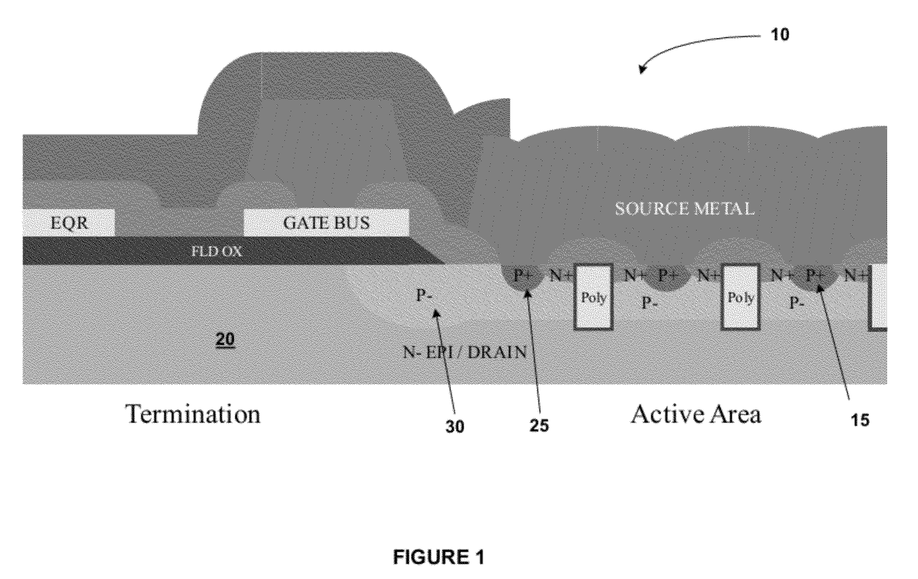

Some embodiments of the semiconductor devices and methods for making such devices are illustrated in FIG. 1 and described herein. The methods include the formation of dopant regions by low temperature microwave (MW) activation of implanted dopants. In some embodiments, the low temperature microwave activation can be used on any dopant region, including heavy body regions, source regions, well regions, base regions, epitaxial layers, or a substrate. In other embodiments, the low temperature microwave activation can be used during formation of heavy body regions.

The dopant regions formed by the MW activation (the MW dopant regions) can be used in any number or type of semiconductor devices. Examples of such semiconductor devices include metal-oxide-semiconductor (MOS) devices, such as CMOS, LDMOS, UMOS, bipolar transistors, BiCMOS, or solar cell devices. In some embodiments, the MW dopant regions can be used in UMOS device, LDMOS devices, or combinations thereof.

One example of a UMOS device is illustrated in FIG. 1. In FIG. 1, the UMOS device 10 contains, among other components, a heavy body dopant region (or heavy body) 15, a source dopant region (or source) 30, and a well dopant region (or well) 25. All of these dopant regions in the device 10 can be formed by implanting dopants into the substrate 20 and then activating the dopants using low temperature MW heating.

In some embodiments, the MW dopant regions can be formed by a process which implants the desired dopant in the appropriate region (i.e., the heavy body region) of the desired semiconductor device and then activates the dopant using any low temperature MW heating process. The initial implantation process can be performed by any known process which can implant the desired dopant material (i.e., B, As, or P) into the desired region of the semiconductor device until the desired concentration is obtained. Using the UMOS device 10 in FIG. 1 as an example, the semiconductor device 10 can be formed as known in the art until the heavy body dopant region 15 needs to be formed. At this point, the desired dopant (such as B) is implanted by any process known in the art. For example, the B dopant can be implanted by a BF₂ source until a concentration of about 1×10¹⁹ atoms/cm³ to about 4×10¹⁹ atoms/cm³ is reached. Other times and temperatures for B (or for the other dopants) can be used to perform the implant process, as known in the art. The BF₂ dose in the heavy body region can be increased as necessary to compensate for the reduced activation of low dose, low mass, and/or low implant energy dopants used by MW processing when compared to RTP processing.

Once the dopant(s) has been implanted into the desired region of the semiconductor structure, it can be activated by using MW energy at a low temperature. In some embodiments, the dopants can be activated with microwaves at any temperature for any time sufficient to activate that particular dopant. In some embodiments, these low temperatures can be less than about 800° C. In other embodiments, these low temperatures can range from about 200 to about 800° C. In yet other embodiments, the temperatures can range from about 200 to about 550° C. In still other embodiments, these low temperatures can be any suitable combination or sub-range of these temperatures.

The MW activation process can use any frequency or wavelength of microwaves that are allowed for industrial applications by government regulations. In some embodiments, the frequency of the microwaves can range from about 2.45 GHz to about 5.8 GHz and have a wavelength ranging from about 52 mm to about 123 mm.

The microwave activation process can be performed for any time sufficient to activate the dopant(s) that have been implanted. In some embodiments, the time can range up to about 10 minutes, which is much shorter than the time of 5 to 6 hours often required for conventional furnace processes or rapid thermal processes (RTP) with times up to two minutes to drive-in the dopants. In some embodiments, the time can range from up to about 5 minutes. In other embodiments, the time can range from about 1 minute to about 2 minutes. In yet other embodiments, the time can be any suitable combination or sub-range of these amounts.

For example, where the dopant comprises B atoms that are activated from a BF₂ implant in the heavy body region of an n-UMOS device, the activation process uses MW energy of about 5.80 GHz, a frequency of about 52 mm wavelength, and temperatures ranging from about 250° C. to about 550° C. In these instances, the activation can be carried out in about 5 minutes without dopant migration into the channel region of the UMOS device.

In another example, where the dopant comprises As or P atoms that are activated in the heavy body region of a p-MOS device, the activation process uses MW energy of about 5.80 GHz, a frequency of about 52 mm wavelength, and temperatures ranging from about 250° C. to about 550° C. In these instances, the activation can be performed in about in about 5 minutes without dopant migration into the channel region of the U-MOS device.

In some embodiments, a combination of rapid thermal processing (RTP) and a low temperature MW radiation can be used to activate the dopants. In these embodiments, the RTP can be performed from about 900 ° C. to about 1100 ° C. for about 30 seconds to about 5 minutes and the MW heating can be performed from about 200 ° C. to about 550 ° C. for about 30 seconds to about 4 minutes. The combination of RTP and MW heating is useful because both dopant activation and elimination of end of range defects can be achieved. In other embodiments, microwave activation after an RTP process could be used to reactivate dopants deactivated during furnace cooling.

In some embodiments, the MW heating processes described herein can also be used during the formation of heavy body regions of other semiconductor devices, such as those described herein. In some embodiments, the MW heating processes described herein can also be used during the formation of well and source regions of UMOS devices, as well as during forming the well and source regions of the other semiconductor devices mentioned herein. In other embodiments, the MW heating processes described herein can also be used during the formation of base regions of bipolar transistors.

In some embodiments, the MW activation processes described above can be used instead of the drive-in processes that are often conventionally used (such as TRP processes) to drive in the dopants after they have been implanted. The drive-in processes are used to diffuse the dopants more uniformly in the desired region since the implant process does not provide a uniform concentration. In other embodiments, though, the MW activation process can be used in addition to such conventional drive-in process.

Using the low temperature MW heating to activate the dopants provides several features. The MW activation process uses lower temperatures than conventional RTP processes that are used during drive-in processes. These lower temperatures result in less dopant migration out of the dopant region that might occur during the higher temperatures used with RTP processes. These lower temperatures also result in less counter-doping (different dopants from adjacent regions creeping into the dopant region) than might occur during the higher temperatures used with RTP processes. As well, these lower temperatures result in a more uniform dopant concentration within the dopant region than can be obtained in higher temperature RTP processing.

This reduced dopant migration can, in turn, lead to several improved device features. First, it can improve the contact resistance between the heavy body dopant region and the source contact. This feature can be achieved because a higher concentration of dopants in the heavy body region due to less out diffusion which occurs during an RTP process. Second, the improved contact resistance can also help control the uncoupled inductive load (UIL). Diffusion of the activated dopant away from the heavy body contact region can lead to increased uncoupled inductive load (UIL) temperature performance of the semiconductor device.

Third, the reduced migration can also provide the ability of lowering the gain of parasitic bipolar transistor in UMOS devices. This ability can be achieved by increasing the active dopant concentration of base region of bipolar semiconductor devices without the dopant migration that results at higher RTP temperatures.

Fourth, the reduced dopant migration can also provide reduced pitch devices with a higher specific resistance (Rsp). This higher resistance can be obtained since the diffusion of the heavy body contact into the channel region of a FET that often occurs during high temperatures in RTP can be reduced or eliminated.

The reduced counter-doping resulting from the lower temperatures can, in turn, lead to several improved device features. First, the activation process allows higher dopant concentrations than can be achieved with conventional drive-in processes using just RTP. As noted above, the higher temperature RTP drive-in processes can often result in counter doping, which lowers the desired dopant concentration (and increases the undesired dopant concentration) in the dopant region. To counteract this counter-doping, boundary layer films (such as lower temperature oxides) were used as diffusion barriers between films containing counter dopants, such as BPSG, and the heavy body region. Thus, the low temperature MW activation process can reduce or eliminate the use of such boundary layer films. Another method to counteract this counter-doping is using wet cleans or rinses that remove the counter dopants that might otherwise diffusion from the surface area of the dopant region into the active area of the region. Again, the low temperature MW activation process can reduce or eliminate the use of such wet cleans/rinses. And the higher dopant concentration allowed by the reduced counter doping can also reduce IDSS fails and gate leakage in reduced pitch devices by eliminating the boundary layer films.

Second, the reduced counter doping can also reduce the processing cost relative to RTP for manufacturing semiconductor devices. Fewer cleans are needed to remove the counter dopant materials that may diffuse into the heavy body region during RTP.

The low temperature MW activation process can improve the control of the threshold voltage (Vt) of the semiconductor devices. This increased control can be obtained since there is little or no diffusion of the dopant in heavy body region into the channel region of the device during the activation region, which can occur at higher temperatures. The improved control of the threshold voltage (Vt) control in UMOS devices can be achieved because of the ability to adjust the source and well implant dopant concentration with less influence from variations in the heavy body etch profile. In some configurations, the only dopant (i.e., B) remaining in the channel after a MW anneal is due to lateral scattering during the implant. This result can be reduced by lowering the HB energy and raising the well dose to achieve the specified Vt.

The low temperature MW activation process can reduce or eliminate the occurrence of snap back in the semiconductor devices. Snap back can occur in situations where the voltage from the drain to the source is reduced by the parasitic bipolar transistor when the device turns on. Snap back is an unwanted effect when the field effect transistor is in the off position.

As well, the microwave dopant activation of the heavy body region, with reduced contribution of the heavy body dopant to the source and well dopants in the channel, can allow simplified adjustment of the source and well implants to optimize Vt when compared to the RdsON for a given device configuration. Higher Vt devices can be adjusted to give a lower Vt with lower RdSON with higher product yield by using the MW activation. And lower Vt devices can have their Vt adjusted closer to the threshold where shoot through would occur without product yield loss.

Further, the Vts of combined semiconductor devices containing LDMOS and/or UMOS devices in either high or low side pairs that are configured to operate at higher frequency, can also be optimized by microwave activation of the heavy body. The tighter control of the Vt of these dual devices allows operation at higher frequency with higher efficiency over a range of RdsON values. The RdsON of these transistor pairs can be optimized, along with minimizing the possibility of shoot through, by controlling the Vt of each transistor (whether UMOS or LDMOS) of the high or low side pair.

Similarly, the use of microwave dopant activation allows control of the Vt and RdsON and smaller physical dimensions for junction formations. Such an ability enables the use of smaller and more cost effective structures and die sizes while achieving the same performance in a UMOS, LDMOS, DMOS, or any diode type structure which can depend on the physical dimensions of a junction (such as zener diodes, schottky diodes, etc.). This feature is particularly useful when creating smaller devices with blended structures in monolithic dies for which the size and dimension of the junction significantly impacts the pitch and size of the final structure, such as N-channel and P-channel structures in monolithic dies, monolithic schotky diodes and transistors, combined planar and trench structures, and/or structures for which the junction is the main structural feature of the die.

Similarly, the use of microwave dopant activation and junction control allows more precise junction interfaces, enabling lower leakage across source, body and heavy body junctions and improving the efficiency performance of DMOS and UMOS transistors. This precise control obtained with the use of microwave dopant activation could therefore allow dimensional tightening of all physical dimensions in the device, leading to tighter design parameters and eliminating masking steps.

It is understood that all material types provided herein are for illustrative purposes only. Accordingly, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

In some embodiments, this application describes a semiconductor device containing a dopant region made by the method comprising providing a substrate, implanting a dopant into the substrate to create a dopant region, and activating the implanted dopant by heating with microwaves at a temperature ranging up to about 800° C.

In some embodiments, this application describes a UMOS semiconductor device containing a dopant region made by the method comprising providing a substrate, implanting a dopant into the substrate to create a source, well, or heavy body region, and activating the implanted dopant by heating with microwaves at a temperature ranging up to about 800° C. for a time.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method for making an semiconductor device containing a dopant region, comprising:
providing a substrate;
implanting a dopant into the substrate to create a dopant region; and
activating the implanted dopant by heating with microwaves at a temperature ranging up to about 800° C.

2. The method of claim 1, wherein the activation temperature ranges from about 150° C. to about 600° C.

3. The method of claim 1, wherein the activation temperature ranges from about 250° C. to about 550° C.

4. The method of claim 1, wherein the dopant region comprises a source, well, or heavy body region of a UMOS semiconductor device.

5. The method of claim 1, wherein the activation process is performed for a time ranging up to about 10 minutes.

6. The method of claim 5, wherein the activation process is performed for a time ranging from about 1 to about 3 minutes.

7. The method of claim 1, wherein the activation process comprises no additional drive-in processes.

8. The method of claim 1, wherein the microwave activation process reduces dopant migration and reduced counter-doping relevant to rapid thermal processing.

9. A method for making a UMOS semiconductor device containing a dopant region, comprising:
providing a substrate;
implanting a dopant into the substrate to create a source, well, or heavy body region; and
activating the implanted dopant by heating with microwaves at a temperature ranging up to about 800° C. for a time.

10. The method of claim 9, wherein the activation temperature ranges from about 150° C. to about 600° C.

11. The method of claim 9, wherein the activation temperature ranges from about 250° C. to about 550° C.

12. The method of claim 9, wherein the activation process is performed for a time ranging up to about 10 minutes.

13. The method of claim 13, wherein the activation process is performed for a time ranging from about 1 to about 3 minutes.

14. The method of claim 9, wherein the activation process comprises no additional drive-in processes.

15. The method of claim 9, wherein the microwave activation process reduces dopant migration and reduced counter-doping relevant to rapid thermal processing.
